(19) United States
(12) Patent Application Publication
(10) Pub. No.: US 2025/0113448 A1
(43) Pub. Date: Apr. 3, 2025

(54) MOLDED MOUNTING FEATURE

(71) Applicant: Our Next Energy, Inc., Novi, MI (US)

(72) Inventors: Daniel James Jilg, Novi, MI (US); Richard Hampo, Ann Arbor, MI (US)

(21) Appl. No.: 18/904,062

(22) Filed: Oct. 1, 2024

Related U.S. Application Data
(60) Provisional application No. 63/587,449, filed on Oct. 3, 2023.

(51) Int. Cl. H05K 5/02; F16B 39/28

(52) U.S. Cl. CPC H05K 5/0217; F16B 39/28

(57) ABSTRACT

An integral mounting feature for attachment of components to a molded plastic housing component or chassis includes an embossment integrally formed with and projecting away from a main generally planar surface of the housing component or chassis, a recess that extends into the embossment from a top of the embossment, and a bore that extends from a side of the embossment perpendicular to the depth direction of the recess and that is connected with the recess.

### RELATED APPLICATIONS

This application claims priority to U.S. Provisional Application No. 63/587,449 filed on Oct. 3, 2023, and is herein incorporated by reference in its entirety.

### FIELD OF THE DISCLOSURE

This disclosure relates to mountings for attaching or securing components to a molded plastic component, and more particularly to mountings that are integrally formed during molding of the plastic component.

### BACKGROUND OF THE DISCLOSURE

In many cases, components can be secured to housing components or chassis using snap-fit joints, heat stakes, or screws or bolts that extend through openings such that the screws or bolts are axially aligned with the line of draw during molding of the housing components or chassis. However, there are occasions when design constraints favor or mandate the use of threaded fasteners that extend perpendicularly to the direction of draw. This usually means the rotational axis of the threaded fastener is parallel with the floor (i.e., main planar surface) of the housing component or chassis. A current method of providing mounting features that use threaded fasteners extending perpendicular to the line of draw involves insert molding of a threaded bushing. While satisfactory, a more cost-effective alternative to insert molding is desired.

### SUMMARY OF THE DISCLOSURE

Described are integral mounting features of a molded plastic component that facilitate attachment or connections using a bolt having an axis of rotation (or length direction) that is perpendicular to the line of draw of the plastic component during demolding (post ejection). The mounting feature includes an embossment that is integrally formed with the molded plastic component and that projects upwardly or away from a main generally planar surface of the component. A recess is formed at a top of the embossment, and a bore is formed through a side of the mounting feature. The bore is perpendicularly to the depth direction of the recess and is connected with the recess.

In certain embodiments, the recess is configured to receive a nut and inhibit rotational and/or axial movement of the nut.

In other embodiments, the recess is configured to receive a flange nut and inhibit both rotational and axial movement of the nut.

In certain embodiments, the recess is configured to allow an end of a bolt to extend through and beyond an end of the nut into a bolt-accommodating section of the recess.

In any of the embodiments, a compression limiter can be inserted into the bore to reduce or prevent compression of the plastic embossment.

### BRIEF DESCRIPTION OF THE DRAWINGS

FIG. 1 is a perspective view of a plastic housing component having integrally molded mounting features in accordance with this disclosure.

FIG. 2 is an enlarged perspective view of the molded mounting feature isolated from the housing component in an assembled state with an inserted nut and compression limiter.

FIG. 3 is an enlarged perspective view of the molding mounting feature before insertion of the nut and compression limiter.

FIG. 4 is a top view of the mounting feature shown in FIG. 2.

FIG. 5 is a cross-sectional view of the mounting as seen along lines 5-5 of FIG. 4.

FIG. 6 is a partial cross-sectional view of a tool having bypassing cores to facilitate molding of a housing component with the integrally molded mounting feature shown in FIGS. 2-5.

FIG. 7 is a perspective view of an application in which the disclosed mounting feature is used to electrically connect a bus bar to an electrical lead of an overcurrent protection device.

### DETAILED DESCRIPTION

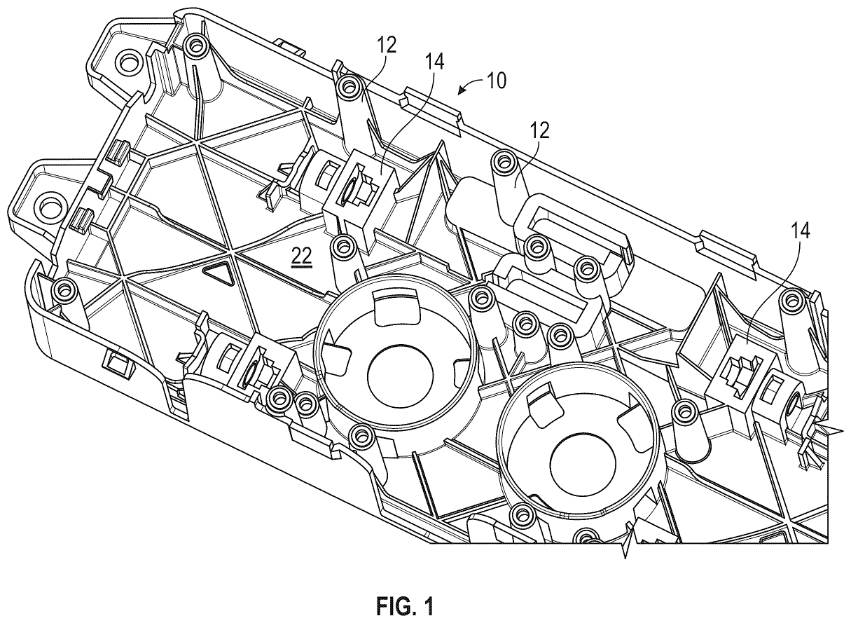

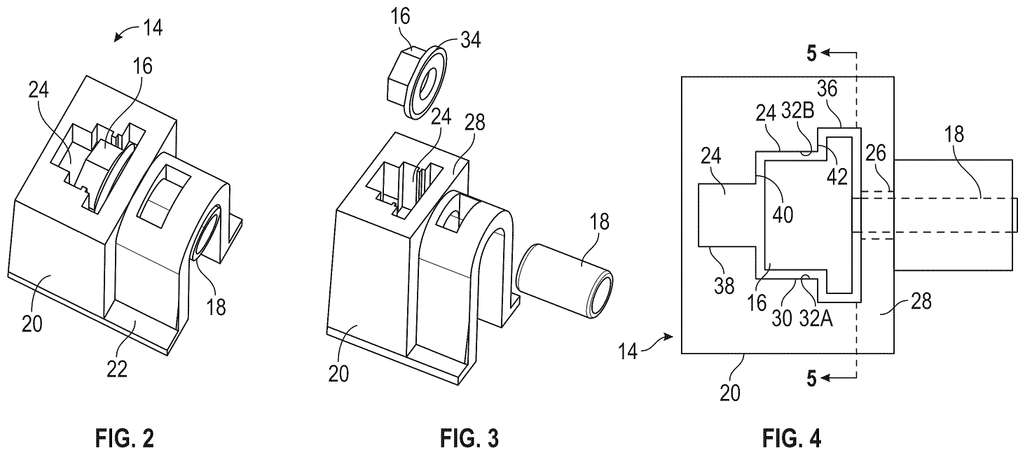

Shown in FIG. 1 is a housing component 10 having various types of mounting features, including vertical mounting features 12 and horizontal mounting features 14, which are the focus of this disclosure. A view of the mounting feature 14 with inserted flange nut 16 and compression limiter 18 is shown (in FIG. 2) for purposes of illustration in isolation from the plastic housing component 10. However, as indicated in FIG. 1, mounting feature 14 is integrally molded with and as part of housing component 10. FIG. 3 shows mounting feature 14 before insertion of nut 16 and compression limiter 18.

Mounting feature 14 may be described as an embossment 20 that rises or protrudes upwardly or away from a generally planar surface 22 of a housing component 10, or from a chassis (e.g., a framework on to which components are assembled, and which can be fastened into a separate housing). A recess 24 extends into the embossment from a top of the embossment that is distal from surface 22. A bore 26 (represented by dashed lines in FIG. 4) extends through wall 28 to recess 24 along a direction perpendicular to the depth direction of the recess, such that bore 26 and recess 24 are joined.

Recess 24 is configured to receive nut 16, such as in a manner that limits or prevents axial and/or rotational movement of nut 16 when a bolt is threaded into nut 16. To prevent or limit rotational movement of nut 16, recess 24 is provided with a nut-receiving section 30 defined by parallel side walls 32A, 32B that are perpendicular to surface 22. Side walls 32A, 32B are spaced apart by a distance that is slightly greater than the distance between opposite flat sides of the head of nut 16, such that nut 18 can be easily inserted in recess 24 with flat sides of nut 16 in close proximity to respective side walls 32A, 32B to prevent or limit rotation of nut 16 when a torque is applied to the nut.

Nut 18 can be a flange nut having a rim 34 (or flange) that can serve a washer-type function to more uniformly distribute compressive loads on to wall 28. To accommodate flange 34, recess 24 is provided between section 30 and wall 28 with an enlarged flange-receiving section 36 that is wider from side-to-side than nut-receiving section 30.

Compression limiter 18 can be inserted through bore 26 to allow contact with nut 16. Compression limiter 18 can be made of a metal tube, such as steel or aluminum, having a wall thickness sufficient to avoid compression of compression limiter 18.

Recess 24 can be provided with a bolt-accommodation section 38 that has a side-to-side dimension or width that is less than the side-to-side (34A to 34B) dimension of nut-receiving section 30. This allows a distal end of a bolt (not shown) that is opposite a head 64 of the bolt to pass through nut 18 and into space defined by section 38.

Recess 24 can be configured with steps 40 and 42 (approximately right-angled corners) that limit or prevent axial movement of nut 18.

While illustrated nut 16 has a hexagonal head with six (6) sides, a nut with more sides (e.g., eight) or fewer sides (e.g., 4) are possible.

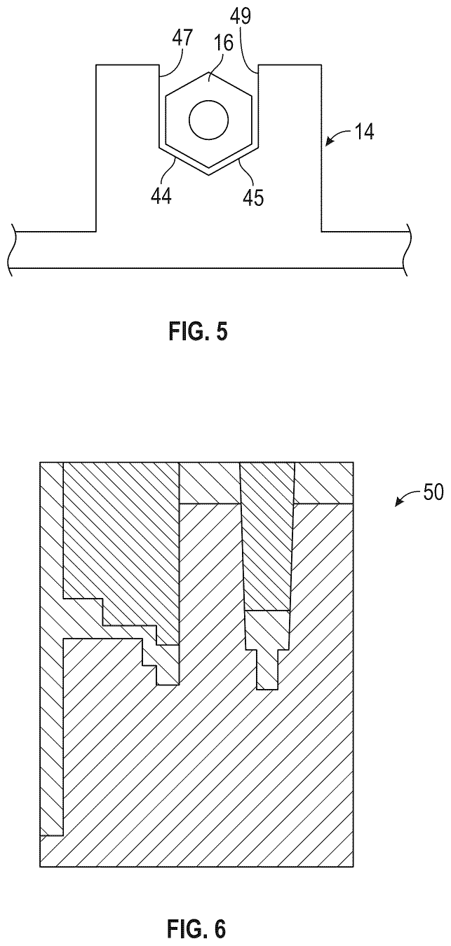

In the case of a hexagonal head, nut-receiving section 30 can be provided with sloped planar bottom surfaces 44, 45 (arranged in a V-shape), as shown in FIG. 5. Surfaces 44, 45 conform with two adjacent side surfaces of hexagonal nut 16, and side surfaces 47, 49 conform with two other sides of nut 16. Together, surfaces 44, 45, 47 and 49 position nut 16 in alignment with bore 26 and prevent rotation of nut 16 when a bolt is threaded into nut 16.

Bore 26 and compression limiter 18 can be cylindrically shaped. However, other shapes are possible.

FIG. 6 illustrates a section of a tool 50 for molding a plastic housing component 10 or chassis having a horizontal mounting feature 14. Tool 50 includes a top core 52 and a bottom core 54 that have bypassing sections that contact each other to facilitate molding of the vertical recess and perpendicular (horizontal) bore, without requiring complicated and expensive side actions such as cams, lifters or sliders.

Component 10 with integrally formed mounting feature 14 can be made from thermoplastic materials using injection molding processes and tools.

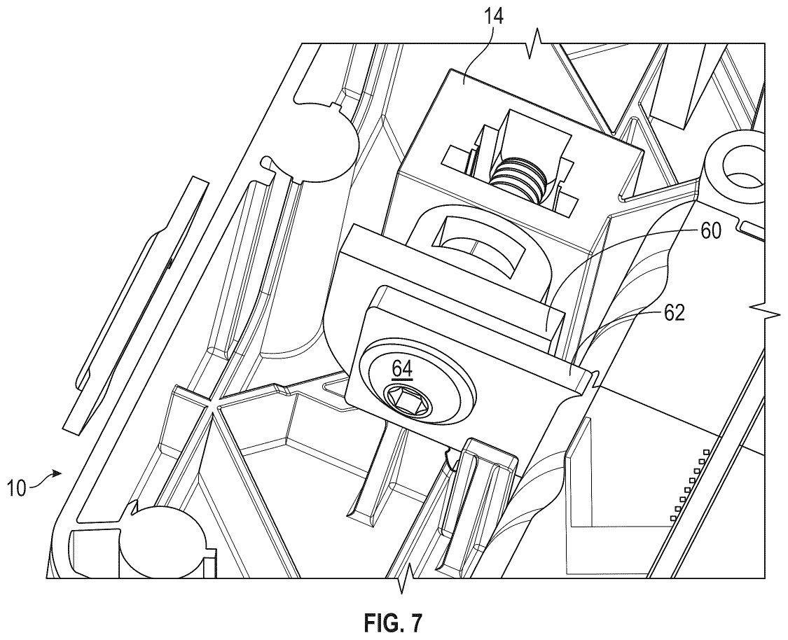

Shown in FIG. 7 is an exemplary application of disclosed mounting feature 14 used for bolting a bus bar 60 to a metal lead 62 of an overcurrent protection device such as a pyrofuse using bolt 64 to achieve a stable electrical connection.

While the present invention is described herein with reference to illustrated embodiments, it should be understood that the invention is not limited hereto. Those having ordinary skill in the art and access to the teachings herein will recognize additional modifications and embodiments within the scope thereof. Therefore, the present invention is limited only by the claims attached herein.

1. An integral mounting feature in a molded plastic component, comprising:
an embossment integrally formed with and projecting from a generally planar surface of the molded plastic component, the embossment having a recess extending into the embossment from a top of the embossment distal from the generally planar surface, and a bore extending in a direction perpendicular to a depth direction of the recess and connected with the recess.

2. The mounting feature of claim 1, wherein the recess includes a nut-receiving section having parallel side walls perpendicular to the generally planar surface and a nut received in the recess between the parallel side walls, the nut sized to have opposite sides that are each in sufficiently close proximity to a respective one of the parallel side walls to prevent rotation of the nut when a torque is applied to the nut.

3. The mounting feature of claim 2, wherein the recess further comprises an enlarged flange-receiving section relative to the nut-receiving section, the enlarged flange-receiving section located between the nut-receiving section and the bore; and the nut including a flange received in the flange-receiving section of the recess.

4. The mounting feature of claim 3, further comprising a compression limiter disposed in the bore with a first end of the bore engaged with the nut.

5. The mounting feature of claim 3, wherein the recess further comprises a bolt-accommodating section located on a side of the nut-receiving section that is opposite of the side adjacent the enlarged flange-receiving section, the bolt-accommodating section having a side-to-side dimension less than that of the nut-receiving recess.

6. The mounting feature of claim 5, wherein lateral dimensions and axial dimensions of the flange-receiving, nut-receiving and bolt-accommodating sections of the recess have a stepped configuration that limits or prevents axial movement of the nut.

7. The mounting feature of claim 2, wherein the nut-receiving section of the recess has sloped planar bottom surfaces conforming with side surfaces of the nut to position the nut in alignment with the bore.

8. The mounting feature of claim 4, wherein the bore has cylindrical walls and the compression limiter has a cylindrical tube shape.

9. The mounting feature of claim 8, wherein the compression limiter is composed of metal.

10. The mounting feature of claim 1, integrally molded as part of a housing component or chassis for supporting electrical components.
